(19) United States
(12) Patent Application Publication
(10) Pub. No.: US 2022/0117117 A1
(43) Pub. Date: Apr. 14, 2022

(54) ELECTRONIC APPARATUS AND METHOD FOR CONTROLLING ELECTRONIC APPARATUS

(71) Applicant: FUJITSU LIMITED, Kawasaki-shi (JP)

(72) Inventors: Masanori Tachibana, Yokohama (JP); KENJI SASABE, Kawasaki (JP)

(73) Assignee: FUJITSU LIMITED, Kawasaki-shi (JP)

(21) Appl. No.: 17/382,404

(22) Filed: Jul. 22, 2021

(30) Foreign Application Priority Data
Oct. 14, 2020 (JP) 2020-173136

(51) Int. Cl. H05K 7/20; G05B 19/4155; G05B 19/416

(52) U.S. Cl. CPC H05K 7/20281; H05K 7/20272; G05B 2219/49216; G05B 19/416; G05B 19/4155

(57) ABSTRACT

An electronic apparatus includes a flow rate control circuit that controls a plurality of flow rate adjusting mechanisms, based on desired flow rates of the coolant for a plurality of electronic circuits and information that indicates relationships between pressure losses and flow rates in a plurality of routes that include internal flow passages of the plurality of electronic circuits, a plurality of distribution pipes, a plurality of discharge pipes, and the plurality of flow rate adjusting mechanisms and in which the coolant flows between the first pipe and the second pipe.

### CROSS-REFERENCE TO RELATED APPLICATION

This application is based upon and claims the benefit of priority of the prior Japanese Patent Application No. 2020-173136, filed on Oct. 14, 2020, the entire contents of which are incorporated herein by reference.

### FIELD

The embodiments discussed herein are related to an electronic apparatus and a method for controlling an electronic apparatus.

### BACKGROUND

With an increase in power consumption of a heat generator such as a central processing unit (CPU) mounted in an electronic unit, an increase in the number of heat generators mounted per unit area, and so on, the case of cooling the electronic unit by using a water-cooling system instead of performing cooling by using an air-cooling system is increasing. For example, it is known that a supply amount of coolant is made appropriate by controlling, based on a flow rate or temperature of the coolant flowing inside an electronic unit, a valve that adjusts the flow rate of the coolant. It is known that, in order to omit a flowmeter that may cause a pressure loss or the like, a flow rate of coolant is calculated based on an amount of heat generated by a heat generator mounted in an electronic unit, a temperature of the heat generator, and a temperature of the coolant. It is known that a monitor flow passage is provided between a supply-side manifold and a discharge-side manifold respectively located at inlets and outlets of a plurality of electronic units and a supply amount of coolant to the plurality of electronic units is made appropriate by adjusting a flow rate of the coolant that flows through this flow passage.

Japanese Laid-open Patent Publication No. 2005-228216, Japanese Laid-open Patent Publication No. 2015-79843, and Japanese Laid-open Patent Publication No. 2018-125497 are disclosed as related art.

### SUMMARY

According to an aspect of the embodiments, an electronic apparatus includes: a plurality of electronic units of two or more kinds, that are housed in a rack and that have respective internal flow passages through which coolant flows; a first pipe that is supplied with the coolant to flow through the internal flow passages of the plurality of electronic units; a second pipe in which the coolant discharged from the plurality of electronic units joins together; a plurality of distribution pipes that distribute the coolant from the first pipe to the plurality of electronic units; a plurality of discharge pipes that allow the coolant discharged from the plurality of electronic units to join together in the second pipe; a plurality of flow rate adjusting mechanisms that adjust flow rates of the coolant that flows into the plurality of distribution pipes from the first pipe; and a flow rate control unit that controls the plurality of flow rate adjusting mechanisms, wherein the flow rate control unit controls the plurality of flow rate adjusting mechanisms, based on desired flow rates of the coolant for the plurality of electronic units and information that indicates relationships between pressure losses and flow rates in a plurality of routes that include the internal flow passages of the plurality of electronic units, the plurality of distribution pipes, the plurality of discharge pipes, and the plurality of flow rate adjusting mechanisms and in which the coolant flows between the first pipe and the second pipe.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram of a cooling system of an electronic apparatus according to a first embodiment;

FIG. 2A is a perspective view of an example of an electronic unit;

FIG. 2B is a sectional view of a portion around a heat generator;

FIG. 3 is a schematic diagram of a cooling system of an electronic apparatus according to a comparative example;

FIG. 4 is a schematic diagram of a control system of the electronic apparatus according to the first embodiment;

FIG. 5 is a diagram illustrating an example of a hardware configuration of a control unit;

FIG. 6 is a flowchart illustrating an example of a flow rate adjusting method performed in the electronic apparatus according to the first embodiment;

FIG. 7 is a schematic diagram of a control system of an electronic apparatus according to a second embodiment; and

FIG. 8 is a flowchart illustrating an example of an abnormal route identifying method and an optimizing method performed after the occurrence of an abnormal route in the electronic apparatus according to the second embodiment.

### DESCRIPTION OF EMBODIMENTS

A plurality of electronic circuits of two or more kinds may be housed in a single rack. The electronic circuits of different kinds have different amounts of heat generated by heat generators and thus have different desired flow rates of coolant. The electronic circuits of different kinds have different heat generator arrangement layouts. Thus, water-cooling modules that constitute internal flow passages through which the coolant flows have different shapes and/or structures. Thus, the internal flow passages have different pressure losses.

There may be a case where when the coolant is distributed to the plurality of electronic circuits from a main pipe supplied with the coolant, the coolant flows in a concentrated manner through an electronic circuit whose internal flow passage has a smaller pressure loss and does not flow through the other electronic circuits at desired flow rates.

In one aspect, even in the case where a plurality of electronic circuits of two or more kinds are housed in a rack, coolant may flow through the plurality of electronic circuits at desired flow rates.

Embodiments of the present disclosure will be described below with reference to the drawings.

### First Embodiment

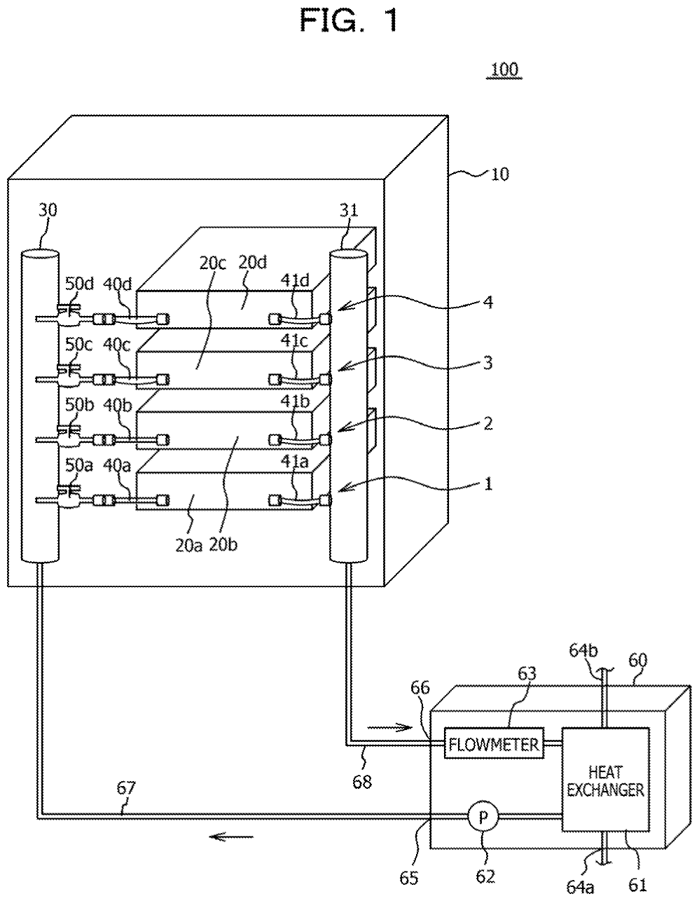

FIG. 1 is a schematic diagram of a cooling system of an electronic apparatus according to a first embodiment. In FIG. 1, a flow direction of coolant is indicated by arrows (the same applies to the similar figures below). As illustrated in FIG. 1, an electronic apparatus 100 according to the first embodiment includes a rack 10, a plurality of electronic units 20a to 20d housed in the rack 10, and a cooling unit 60 that supplies coolant to the plurality of electronic units 20a to 20d. The coolant is cooling water having a temperature of 15° C. to 20° C., for example, but may be other than cooling water. The electronic units 20a to 20d may be, for example, servers. Hereinafter, the electronic units 20a to 20d may be referred to as electronic units 20 when being collectively expressed.

The cooling unit 60 is, for example, a coolant distribution unit (CDU) and includes a heat exchanger 61, a pump 62, and a flowmeter 63. The heat exchanger 61 is a device that performs heat exchange between primary refrigerant and secondary refrigerant. The primary refrigerant is supplied from a chiller (not illustrated) or a radiator (not illustrated) through a pipe 64a and is returned to the chiller or the radiator through a pipe 64b. In the heat exchanger 61, for example, heat exchange is performed between the primary refrigerant and the secondary refrigerant that are liquid.

The pump 62 is provided between the heat exchanger 61 and a coolant discharge port 65 of the cooling unit 60 on the downstream side of the heat exchanger 61 in a flow passage of the coolant (the secondary refrigerant). The pump 62 suctions and discharges the coolant cooled in the heat exchanger 61. The pump 62 may be a pump of a variable discharge flow rate type or a pump of a fixed discharge flow rate type. The pump 62 is, for example, an electric pump. The pump 62 has a capacity that enables the supply of the coolant to the plurality of electronic units 20a to 20d at a desired total flow rate.

The flowmeter 63 is provided between the heat exchanger 61 and a coolant receiving port 66 of the cooling unit 60. The flowmeter 63 measures the total flow rate of the coolant supplied to the electronic units 20a to 20d from the cooling unit 60. There may be a case where the flowmeter 63 is provided between the heat exchanger 61 and the coolant discharge port 65, for example, between the pump 62 and the coolant discharge port 65.

The rack 10 is equipped with a main pipe 30 (first pipe) through which the coolant supplied from the cooling unit 60 flows and with a main pipe 31 (second pipe) through which the coolant discharged from the electronic units 20a to 20d joins together. The main pipes 30 and 31 are metal pipes made of, for example, copper, stainless steel, or the like. The main pipe 30 is coupled to the coolant discharge port 65 of the cooling unit 60 by a coupling pipe 67. The main pipe 31 is coupled to the coolant receiving port 66 of the cooling unit 60 by a coupling pipe 68. The main pipes 30 and 31 and the coupling pipes 67 and 68 form a flow passage through which the coolant flows.

The main pipe 30 and the plurality of electronic units 20a to 20d are coupled to each other by a plurality of distribution pipes 40a to 40d, respectively. Thus, the coolant is distributed from the main pipe 30 to the plurality of electronic units 20a to 20d. The main pipe 31 and the plurality of electronic units 20a to 20d are coupled to each other by a plurality of discharge pipes 41a to 41d, respectively. Thus, the coolant discharged from the plurality of electronic units 20a to 20d joins together in the main pipe 31. The distribution pipes 40a to 40d and the discharge pipes 41a to 41d are, for example, hoses with couplers and form the flow passage through which the coolant flows. The distribution pipes 40a to 40d may be referred to as distribution pipes 40 when being collectively expressed. The discharge pipes 41a to 41d may be referred to as discharge pipes 41 when being collectively expressed.

The coolant supplied to the main pipe 30 from the cooling unit 60 is distributed to the electronic units 20a to 20d by the distribution pipes 40a to 40d, respectively. The coolant discharged from the electronic units 20a to 20d joins together in the main pipe 31 by the discharge pipes 41a to 41d, respectively. The coolant that has joined together in the main pipe 31 returns to the cooling unit 60. In this way, the coolant circulates between the cooling unit 60 and the electronic units 20a to 20d.

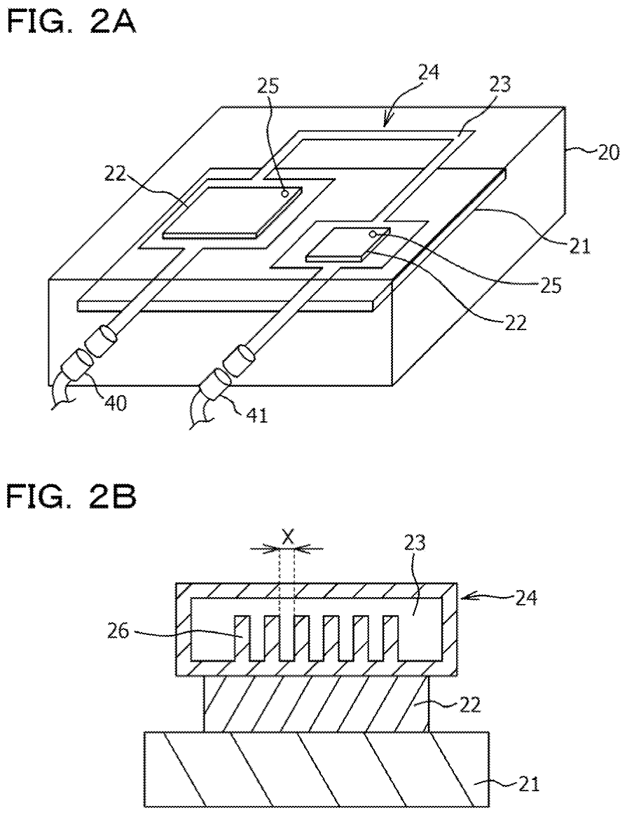

FIG. 2A is a perspective view of an example of an electronic unit. FIG. 28 is a sectional view of a portion around a heat generator. As illustrated in FIG. 2A, the electronic unit 20 includes a wiring board 21, one or a plurality of heat generators 22 mounted over the wiring board 21, and a water-cooling module 24 having an internal flow passage 23 through which coolant for cooling the heat generators 22 flows. One end of the internal flow passage 23 is coupled to the distribution pipe 40, and the other end of the internal flow passage 23 is coupled to the discharge pipe 41. The heat generator 22 is, for example, a heat generating component, such as a CPU, that operates and consequently generates heat. The heat generator 22 may be equipped with a thermometer 25 that measures a temperature of the heat generator 22.

As illustrated in FIG. 2B, the water-cooling module 24 has a plurality of heat dissipation fins 26 in the internal flow passage 23 and is provided so that the coolant passes over the heat generator 22. The heat dissipation fins 26 are provided so as to be located over the heat generator 22. The coolant flows through the internal flow passage 23 including portions between the plurality of heat dissipation fins 26. The coolant flows through the internal flow passage 23, so that heat exchange is performed between heat generated by the heat generator 22 and the coolant and the heat generator 22 is cooled. The cooling effect may be enhanced by providing the heat dissipation fins 26 in the internal flow passage 23. An interval X of the plurality of heat dissipation fins 26 is, for example, about 0.5 mm. FIG. 2B illustrates, by way of example, the case where the heat dissipation fins 26 and the water-cooling module 24 are formed integrally. However, there may be a case where the heat dissipation fins 26 is not integrated with the water-cooling module 24.

In FIG. 1, the plurality of electronic units 20a to 20d are electronic units, according to two or more kinds of specifications, that implement different functions. In the first embodiment, a case where the electronic units 20a to 20d are electronic units of kinds different from one another (according to different specifications) will be described by way of example. When the kinds of the electronic units are different, amounts of heat generated by the heat generators 22 are different. Since arrangement layouts of the heat generators 22 are different, shapes and/or structures of the water-cooling modules 24 for cooling the heat generators 22 are different. If the amounts of heat generated by the heat generators 22 are different, desired flow rates of the coolant for cooling the heat generators 22 and allowing the heat generators 22 to keep operating stably are different. If the shapes and/or structures of the water-cooling modules 24 are different, pressure losses in the internal flow passages 23 are different.

As illustrated in FIG. 1, a plurality of valves 50a to 50d for adjusting flow rates of the coolant that flows from the main pipe 30 to the plurality of distribution pipes 40a to 40d are coupled to the main pipe 30, respectively. One ends of the distribution pipes 40a to 40d are coupled to the valves 50a to 50d, respectively, and the other ends of the distribution pipes 40a to 40d are coupled to the internal flow passages 23 of the electronic units 20a to 20d, respectively. The valves 50a to 50d are, for example, electric valves or electromagnetic valves whose opening degrees are adjustable. In the first embodiment, the case where the valves are coupled to the main pipe 30 is described by way of example. However, the valves may be provided at other locations, such as being coupled to the main pipe 31. In the first embodiment, the case where the valves whose opening degrees are adjustable are described as flow rate adjusting mechanisms that adjust the flow rates of the coolant by way of example. However, there may be other cases. For example, the flow rate adjusting mechanisms may be mechanisms that adjust the sizes of inner diameters of the distribution pipes 40a to 40d and/or the discharge pipes 41a to 41d (for example, opening degrees of the flow passages).

A route for the coolant that flows from the main pipe 30 to the main pipe 31 through the valve 50a, the distribution pipe 40a, the internal flow passage 23 of the electronic unit 20a, and the discharge pipe 41a is referred to as a route 1. Likewise, a route for the coolant that flows from the main pipe 30 to the main pipe 31 through the valve 50b, the distribution pipe 40b, the internal flow passage 23 of the electronic unit 20b, and the discharge pipe 41b is referred to as a route 2. A route for the coolant that flows from the main pipe 30 to the main pipe 31 through the valve 50c, the distribution pipe 40c, the internal flow passage 23 of the electronic unit 20c, and the discharge pipe 41c is referred to as a route 3. A route for the coolant that flows from the main pipe 30 to the main pipe 31 through the valve 50d, the distribution pipe 40d, the internal flow passage 23 of the electronic unit 20d, and the discharge pipe 41d is referred to as a route 4. Therefore, the routes 1 to 4 are coupled in parallel to each other between the main pipe 30 and the main pipe 31.

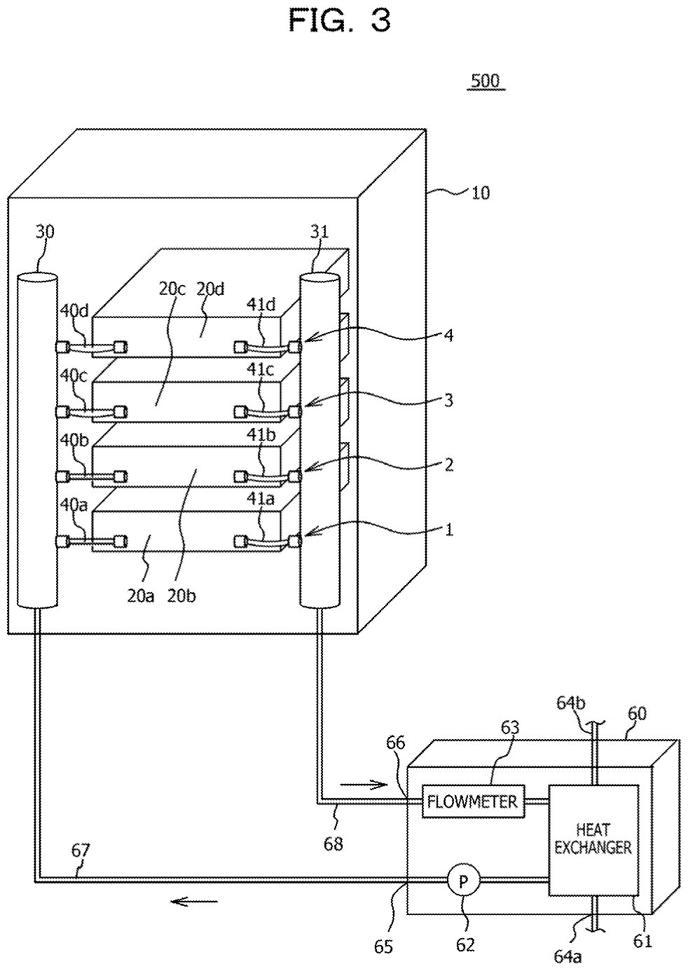

FIG. 3 is a schematic diagram of a cooling system of an electronic apparatus according to a comparative example. As illustrated in FIG. 3, in an electronic apparatus 500 according to the comparative example, no valve is coupled to the main pipe 30. One ends of the distribution pipes 40a to 40d are coupled to the main pipe 30, and the other ends of the distribution pipes 40a to 40d are coupled to the internal flow passages 23 of the electronic units 20a to 20d, respectively. Since other configurations are the same as those of the first embodiment, description is omitted.

A case is assumed where all of the electronic units 20a to 20d in the electronic apparatus 500 according to the comparative example are electronic units of the same kind (specification) configured in the same manner to implement the same function. In this case, the electronic units 20a to 20d have the same amount of heat generated by the heat generators 22, and the water-cooling modules 24 through which the coolant for cooling the heat generators 22 flows have the same shape and structure. Therefore, the electronic units 20a to 20d have the same desired flow rate of the coolant and have the same pressure loss in the internal flow passages 23. In this case, the coolant supplied from the cooling unit 60 to the main pipe 30 is equally distributed to the electronic units 20a to 20d if the pressure losses in the distribution pipes 40a to 40d are equal to each other and the pressure losses in the discharge pipes 41a to 41d are equal to each other. Thus, by supplying the coolant from the cooling unit 60 to the main pipe 30 at a desired total flow rate for the electronic units 20a to 20d, the coolant is supplied to each of the electronic units 20a to 20d at the desired flow rate. For example, in the case where the desired flow rate of the coolant per electronic unit is Q [L/min], if the coolant is supplied from the cooling unit 60 at 4Q [L/min], the coolant is supplied to each of the electronic units 20a to 20d at Q [L/min].

However, electronic units, of two or more kinds of specifications, that implement different functions may be housed in the rack 10. A case is assumed where the electronic units 20a, 20b, and 20c are electronic units of the same kind and the electronic unit 20d is an electronic unit of a kind different from the kind of the electronic unit 20a, 20b, and 20c in the electronic apparatus 500 according to the comparative example. In this case, the amount of heat generated by the heat generator 22 is different between each of the electronic units 20a to 20c and the electronic unit 20d. Thus, the desired flow rate of the coolant for each of the electronic units 20a to 20c is different from the desired flow rate of the coolant fbr the electronic unit 20d. The arrangement layout of the heat generator 22 is different between each of the electronic units 20a to 20c and the electronic unit 20d. Thus, the shapes and/or structures of the water-cooling modules 24 are different and the pressure losses in the internal flow passages 23 are different. A case is assumed where the pressure loss in the internal flow passage 23 of the electronic unit 20d is smaller than the pressure loss in the internal flow passages 23 of each of the electronic units 20a to 20c. In this case, even if the coolant is supplied from the cooling unit 60 to the main pipe 30 at the desired total flow rate for the electronic units 20a to 20d, the coolant flows in a concentrated manner through the electronic unit 20d whose internal flow passage 23 has a smaller pressure loss. As a result, the coolant may not flow through each of the electronic units 20a to 20c at the desired flow rate. If a pump having a high supply capacity is used as the pump 62 of the cooling unit 60 so that the coolant flows also in each of the electronic units 20a to 20c at the desired flow rate, the power consumption of the cooling unit 60 increases.

Accordingly, description will be given below of a method for causing the coolant to flow through the electronic units 20a to 20d at the desired flow rates without increasing the supply capacity of the pump 62 even in the case where the electronic units 20a to 20d of two or more kinds are housed in the rack 10.

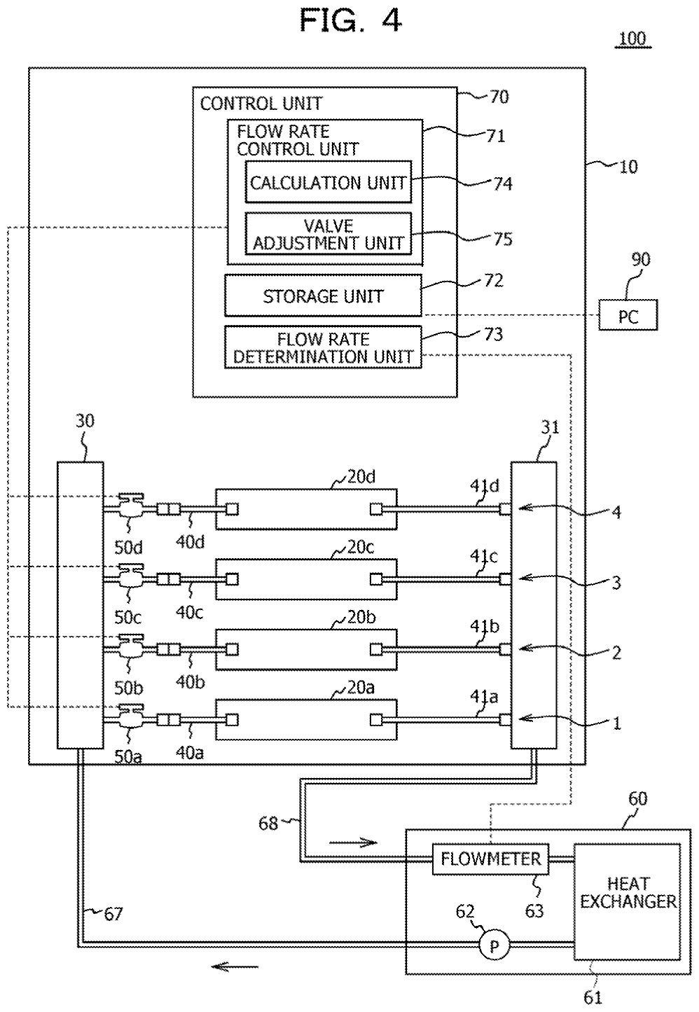

FIG. 4 is a schematic diagram of a control system of the electronic apparatus according to the first embodiment. In FIG. 4, control lines relating to a control unit 70 are indicated by dotted lines. FIG. 4 also illustrates the cooling system illustrated in FIG. 1. As illustrated in FIG. 4, the electronic apparatus 100 according to the first embodiment includes the control unit 70 in the rack 10. The control unit 70 includes a flow rate control unit 71, a storage unit 72, and a flow rate determination unit 73. The flow rate control unit 71 includes a calculation unit 74 and a valve adjustment unit 75. The calculation unit 74 performs calculation for determining the opening degree of a valve. The valve adjustment unit 75 changes the opening degrees of the valves 50a to 50d. In this manner, the flow rate control unit 71 controls the valves 50a to 50d. The storage unit 72 stores information used in calculation performed by the calculation unit 74. The storage unit 72 loads information from an external terminal, for example, a personal computer (PC) 90 and stores the information. The flow rate determination unit 73 receives a detection signal (flow rate pulse signal) of the flowmeter 63 included in the cooling unit 60 and determines, based on the received result, whether the coolant is flowing through the electronic units 20a to 20d at desirable flow rates.

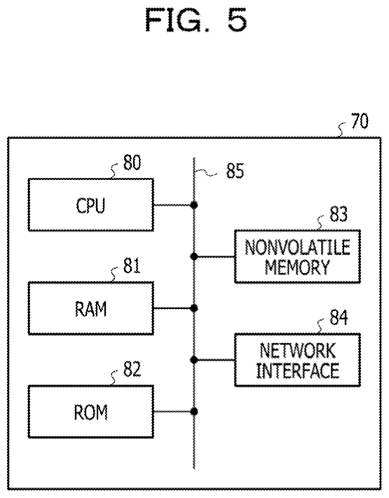

FIG. 5 is a diagram illustrating an example of a hardware configuration of a control unit. As illustrated in FIG. 5, the control unit 70 includes a CPU 80, a random-access memory (RAM) 81, a read-only memory (ROM) 82, a nonvolatile memory 83, and a network interface 84. Each of these components is coupled to a bus 85. The nonvolatile memory 83 is, for example, a hard disk drive (HDD), a flash memory, or the like. The nonvolatile memory 83 corresponds to the storage unit 72 in FIG. 4. The flow rate control unit 71 and the flow rate determination unit 73 are implemented by cooperation of hardware such as the CPU 80 and software stored in the nonvolatile memory 83 or the like. The flow rate control unit 71 and the flow rate determination unit 73 may be an exclusively designed circuit. The flow rate control unit 71 and the flow rate determination unit 73 may be a single circuit or may be different circuits. The network interface 84 is an interface between the control unit 70 and a peripheral device having a communication function and coupled via a network constructed by a data transmission channel such as a wired and/or wireless network.

Tables 1 to 4 are examples of information stored in the storage unit 72. Table 1 is an example of characteristic information on electronic units mounted in the rack 10. As illustrated in Table 1, the storage unit 72 stores, as the characteristic information on the electronic units, the kind of each electronic unit, the desired flow rate of the coolant for the electronic unit, and information on P-Q characteristics indicating a relationship between the pressure loss and the flow rate in the internal flow passage of the electronic unit. As described above, when the kinds of the electronic units are different such as A to X, the desired flow rates of the coolant for the electronic units are different such as Q_{A} to Q_{X}. It is commonly known that the P-Q characteristics (pressure loss-flow rate characteristics) indicating the relationship between the pressure loss and the flow rate is approximated by ΔP=αQ^{β} (where α and β are coefficients) in the case where ΔP denotes the pressure loss and Q denotes the flow rate. The coefficients α and β change depending on the kind of the coolant and/or the shape and structure of the water-cooling module 24 illustrated in FIG. 2 (for example, the cross-sectional area, shape, and the like of the internal flow passage 23). Therefore, as the information on the P-Q characteristics, the coefficients α and β of the P-Q characteristics and information on a pressure loss ΔP_{S} in the internal flow passage 23 when the coolant flows at the desired flow rate are stored for each kind of electronic unit. The pressure loss ΔP_{S} may be calculated when desired instead of being stored.

TABLE 1

| | | | |
|---|---|---|---|
| Kind of | | Coefficients of P-Q | |
| electronic | Desired | characteristics | Pressure |

| unit | flow rate | α | β | loss ΔPs |
|---|---|---|---|---|
| A | Q_{A} | α_{A} | β_{A} | α_{A}Q_{A}^{β}^{_{A}} |
| B | Q_{B} | α_{B} | β_{B} | α_{B}Q_{B}^{β}^{_{B}} |
| C | Q_{C} | α_{C} | β_{C} | α_{C}Q_{C}^{β}^{_{C}} |
| D | Q_{D} | α_{D} | β_{D} | α_{D}Q_{D}^{β}^{_{D}} |
| . | . | . | . | . |
| . | . | . | . | . |
| . | . | . | . | . |
| X | Q_{X} | α_{X} | β_{X} | α_{X}Q_{X}^{β}^{_{X}} |

Table 2 illustrates an example of characteristic information on distribution pipes and discharge pipes. As illustrated in Table 2, the storage unit 72 stores, as the characteristic information on the distribution pipes and the discharge pipes, the kind of the pipe (for example, the kind of the hose) and information on P-Q characteristics indicating a relationship between the pressure loss and the flow rate in the pipe. Also for the distribution pipes and the discharge pipes, the coefficients α and β of the P-Q characteristics change depending on the shape and/or structure of the pipe. Thus, the coefficients α and β of the P-Q characteristics are stored as the information on the P-Q characteristics. In Table 2, a pressure loss ΔP_{H} when the coolant flows through a pipe I at a flow rate Q_{A} is denoted by ΔP_{H}=α₁Q_{A}\hat{ }β₁. The same applies to the other pipes.

TABLE 2

Coefficients of P-Q
characteristics

| Kind of pipe | α | β |
|---|---|---|
| I | α_{I} | β_{I} |
| II | α_{II} | β_{II} |
| III | α_{III} | β_{III} |
| IV | α_{IV} | β_{IV} |
| . | . | . |
| . | . | . |
| . | . | . |
| X | α_{X} | β_{X} |

Table 3 is an example of characteristic information on valves. As illustrated in Table 3, the storage unit 72 stores, as the characteristic information on the valves, information on P-Q characteristics indicating a relationship between the pressure loss and the flow rate in the valve, for each flow rate of the coolant that flows through the valve. When the opening degree of the valve is decreased, the flow passage narrows. Thus, when a parameter indicating the opening degree of the valve is denoted by k (for example, an open/close angle or an open/close rate), a pressure loss ΔP_{V} in the valve is denoted by ΔP_{V}=α_{V}(k)Q\hat{ }(β_{V}(k)) (where α_{V}(k) and β_{V}(k) are coefficients and functions of the opening degree k). For example, when the coolant flows at a desired flow rate Q_{A} for cooling an electronic unit A, the pressure loss ΔP_{V} in the valve is denoted by ΔP_{V}=α_{V}(k)Q_{A}\hat{ }(β_{V}(k)). Since the flow rate Q_{A} is fixed, the above equation may be represented by a simple equation with which the pressure loss is determined according to the opening degree of the valve using the variable k. It is commonly known that the pressure loss ΔP_{V} in a valve when a flow rate is fixed is represented by ΔP_{V}=γk^{δ} (where γ and δ are coefficients and k denotes the opening degree of the valve). Therefore, as the information on the P-Q characteristics of the valve, the coefficients γ and δ are stored for each flow rate of the coolant that flows through the valve. For example, in Table 3, the pressure loss ΔP_{V} when the coolant flows through the valve at the flow rate Q_{A} is denoted by ΔP_{V}=γ_{A}k\hat{ }δ_{A}. The pressure loss ΔP_{V} changes by changing the opening degree k of the valve. The same applies to other flow rates.

TABLE 3

| | |
|---|---|
| Row rate | Valve-specific coefficients |

| in valve | γ | δ |
|---|---|---|
| Q₁ | γ₁ | δ₁ |
| Q₂ | γ₂ | δ₂ |
| Q₃ | γ₃ | δ₃ |
| . | . | . |
| . | . | . |
| . | . | . |
| Q_{A} | γ_{A} | δ_{A} |
| . | . | . |
| . | . | . |
| . | . | . |
| Q_{B} | γ_{B} | δ_{B} |
| . | . | . |
| . | . | . |
| . | . | . |
| Q_{C} | γ_{C} | δ_{C} |
| . | . | . |
| . | . | . |
| . | . | . |
| Q_{D} | γ_{D} | δ_{D} |
| . | . | . |
| . | . | . |
| . | . | . |
| Qₙ | γₙ | δₙ |

The information in Tables 1 to 3 is input to the storage unit 72 from the PC 90 after the information is obtained in advance from design information or the like or after evaluation and measurement are performed in advance by using a commonly known method. Table 3 illustrates the information on the P-Q characteristics in the case where the number of kinds of valves is one. However, in the case where there are a plurality of kinds of valves, information as illustrated in Table 3 may be stored for each of the kinds of valves.

Table 4 illustrates an example of information on the mounted positions of the electronic units in the rack 10 and the kinds of the electronic units mounted at the respective mounted positions. As illustrated in Table 4, the kind of the mounted electronic unit is stored for each of the mounted positions in the rack 10. The information illustrated in Table 4 is input to the storage unit 72 from the PC 90 when the kind and the mounted position of an electronic unit to be mounted in the rack 10 are determined.

TABLE 4

| Mounted position | Kind of electronic unit |
|---|---|
| Route 1 | A |
| Route 2 | B |
| Route 3 | C |
| Route 4 | D |
| . | . |
| . | . |
| . | . |

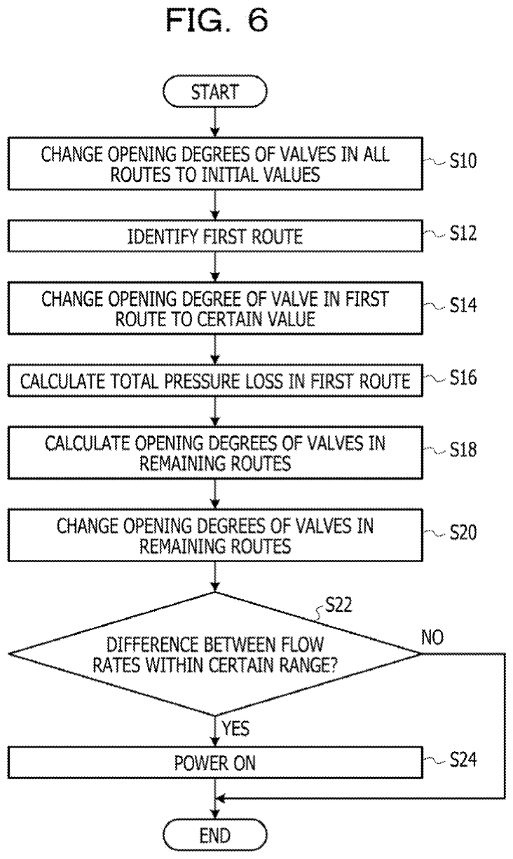

FIG. 6 is a flowchart illustrating an example of a flow rate adjusting method performed in the electronic apparatus according to the first embodiment. As Illustrated in FIG. 6, after the cooling unit 60 starts operating, the flow rate control unit 71 changes the opening degrees of the valves 50a to 50d located in all the routes 1 to 4 to initial values, respectively (step S10). For example, suppose that the opening degrees when the valves 50a to 50d are fully closed are denoted as 0% and the opening degrees when the valves 50a to 50d are fully open are denoted as 100%. In such a case, the opening degrees of the valves 50a to 50d are set to 50%. Consequently, a route in which the valve is closed is not present even in the case where an electronic apparatus is newly installed or an electronic unit is added.

The flow rate control unit 71 identifies, from among the routes 1 to 4, a first route with the largest sum among the sums of the pressure losses in the internal flow passages 23 of the electronic units 20a to 20d, the pressure losses in the distribution pipes 40a to 40d, and the pressure losses in the discharge pipes 41a to 41d, respectively (step S12).

The first route is identified based on Table 1, Table 2, and Table 4 stored in the storage unit 72. In the following description, it is assumed that the electronic units 20a, 20b, 20c, and 20d in the routes 1, 2, 3, and 4 are referred to as electronic units A, B, C, and D, respectively, and that all of the distribution pipes 40a to 40d and of the discharge pipes 41a to 41d are referred to as pipes I. In this case, the flow rate control unit 71 calculates a pressure loss ΔP_{Sa} in the internal flow passage 23 of the electronic unit 20a as ΔP_{Sa}=α_{A}Q_{A}\hat{ }β_{A}. Likewise, the flow rate control unit 71 calculates pressure losses ΔP_{Sb} to ΔP_{Sd} in the internal flow passages 23 of the electronic units 20b to 20d as ΔP_{Sb}=α_{B}Q_{B}\hat{ }β_{B}, ΔP_{Sc}=α_{C}Q_{C}\hat{ }β_{C}, and ΔP_{Sd}=α_{D}Q_{D}\hat{ }βB_{D}, respectively. The flow rate control unit 71 calculates a pressure loss ΔP_{Ha} in each of the distribution pipe 40a and the discharge pipe 41a as ΔP_{Ha}=α_{I}Q_{A}\hat{ }β_{I}. Likewise, the flow rate control unit 71 calculates a pressure loss ΔP_{Hb} in each of the distribution pipe 40b and the discharge pipe 41b as ΔP_{Hb}=α_{I}Q_{B}\hat{ }β_{I}. The flow rate control unit 71 calculates a pressure loss ΔP_{Hc} in each of the distribution pipe 40c and the discharge pipe 41c as ΔP_{Hc}=α_{I}Q_{C}\hat{ }β_{I}. The flow rate control unit 71 calculates a pressure loss ΔP_{Hd} in each of the distribution pipe 40d and the discharge pipe 41d as ΔP_{Hd}=α_{I}Q_{D}\hat{ }β_{I}. Based on the calculation results of these pressure losses, the flow rate control unit 71 identifies, as a first route, from among the routes 1 to 4, a route with the largest sum among sums of the pressure losses in the internal flow passages 23 of the electronic units 20a to 20d, the pressure losses in the distribution pipes 40a to 40d, and the pressure losses in the discharge pipes 41a to 41d, respectively.

The flow rate control unit 71 changes the opening degree of the valve located in the first route identified in step S12 to a certain value k_{A} that is larger than the initial value (step S14). For example, in the case where the first route is the route 1, the flow rate control unit 71 changes the opening degree of the valve 50a located in the route 1 to 80%. The case is preferable where the certain value of the opening degree of the valve is not 100% but a value smaller than 100%, for example, 70% to 90%. This is for leaving room for increasing the opening degree to identify an abnormal route described in a second embodiment.

The flow rate control unit 71 calculates a total pressure loss ΔP₁ of the pressure loss in the internal flow passage of the electronic unit, the pressure loss in the distribution pipe, the pressure loss in the discharge pipe, and the pressure loss in the valve in the first mute (step S16). The total pressure loss ΔP₁ in the first route is calculated based on Tables 1 to 4. For example, it is assumed that the first route is the route 1 and the opening degree of the valve 50a located in the route 1 is 80%. In this case, the pressure loss ΔP_{Sa} in the internal flow passage 23 of the electronic unit 20a located in the route 1 is calculated as ΔP_{Sa}=α_{A}Q_{A}\hat{ }β_{A}, and the pressure loss ΔP_{Ha} in each of the distribution pipe 40a and the discharge pipe 41a located in the route 1 is calculated as ΔP_{Ha}=α_{I}Q_{A}\hat{ }B_{I}. A pressure loss ΔP_{Va} in the valve 50a located in the route 1 is calculated as ΔP_{Va}=γ_{A}k₈₀\hat{ }δ_{A}. Therefore, the flow rate control unit 71 calculates, as the total pressure loss ΔP₁ in the route 1, ΔP₁=ΔP_{Sa}+2ΔP_{Ha}+ΔP_{Va}. The pressure loss ΔP_{Sa} in the internal flow passage 23 of the electronic unit 20a and the pressure loss ΔP_{Ha} in each of the distribution pipe 40a and the discharge pipe 41a are constants. The pressure loss ΔP_{Va} in the valve 50a is also a constant since the opening degree of the valve 50a is fixed. Therefore, ΔP₁ is A (constant).

The flow rate control unit 71 calculates the opening degree of the valve located in each of the remaining routes other than the first route such that the total pressure loss in the remaining route is equal to the total pressure loss in the first route (step S18). For example, a total pressure loss ΔP₂ in the route 2 is calculated as ΔP₂=ΔP_{Sb}+2ΔP_{Hb}+ΔP_{Vb}. ΔP_{Sb} is calculated as ΔP_{Sb}=α_{B}Q_{B}\hat{ }β_{B}, ΔP_{Hb} is calculated as ΔP_{Hb}=α_{I}Q_{B}\hat{ }β_{I}, and ΔP_{Vb} is calculated as ΔP_{Vb}=γ_{B}k_{B}\hat{ }δ_{B}. Since the pressure loss ΔP_{Sb} in the internal flow passage 23 of the electronic unit 20b and the pressure loss ΔP_{Hb} in each of the distribution pipe 40b and the discharge pipe 41b are constants, ΔP₂ is βP₂=γ_{B}k_{B}\hat{ }δ_{B}+B (constant). Therefore, in order for ΔP₁ and ΔP₂ to be equal to each other, A (constant)=γ_{B}k_{B}\hat{ }δ_{B}+B (constant) is to be satisfied. Thus, an opening degree k_{B} of the valve 50b is calculated as in Equation 1 below.

$${k}_{B} = \sqrt[{δ}_{B}]{\frac{A - B}{{γ}_{B}}}$$

Likewise, a total pressure loss ΔP₃ in the route 3 is calculated as ΔP₃=ΔP_{Sc}+2ΔP_{Hc}+ΔP_{Vc}. ΔP_{Sc} is calculated as ΔP_{Sc}=α_{C}Q_{C}\hat{ }β_{C}, ΔP_{Hc} is calculated as ΔP_{Hc}=α_{I}Q_{I}\hat{ }β_{I}, and ΔP_{Vc} is calculated as ΔP_{Vc}=γ_{C}k_{C}\hat{ }δ_{C}. Since the pressure loss ΔP_{Sc} in the internal flow passage 23 of the electronic unit 20c and the pressure loss ΔP_{Hc} in each of the distribution pipe 40c and the discharge pipe 41c are constants, ΔP₃ is ΔP₃=γ_{C}k_{C}\hat{ }δ_{C}+C (constant). Therefore, in order for ΔP₁ and ΔP₃ to be equal to each other, A (constant)=γ_{C}k_{C}\hat{ }δ_{C}+C (constant) is to be satisfied. Thus, an opening degree k_{C} of the valve 50c is calculated as in Equation 2 below.

$${k}_{C} = \sqrt[{δ}_{C}]{\frac{A - C}{{γ}_{C}}}$$

A total pressure loss ΔP₄ in the route 4 is calculated as ΔP₄=ΔP_{Sd}+2ΔP_{Hd}+ΔP_{Vd}. ΔP_{Sd} is calculated as ΔP_{Sd}=α_{D}Q_{D}\hat{ }β_{D}, ΔP_{Hd} is calculated as ΔP_{Hd}=α₁Q₁\hat{ }β₁, and ΔP_{Vd} is calculated as ΔP_{Vd}=γ_{D}k_{D}\hat{ }δ_{D}. Since the pressure loss ΔP_{Sd} in the internal flow passage 23 of the electronic unit 20d and the pressure loss ΔP_{Hd} in each of the distribution pipe 40d and the discharge pipe 41d are constants, ΔP₄ is ΔP₄=γ_{D}k_{D}\hat{ }δ_{D}+D (constant). Therefore, in order for ΔP₁ and ΔP₄ to be equal to each other, A (constant)=γ_{D}k_{D}\hat{ }δ_{D}+D (constant) is to be satisfied. Thus, an opening degree k_{D} of the valve 50d is calculated as in Equation 3 below.

$${k}_{D} = \sqrt[{δ}_{D}]{\frac{A - D}{{γ}_{D}}}$$

The flow rate control unit 71 changes the opening degrees of the valves located in the remaining routes to the respective opening degrees of the valves calculated in step S18 (step S20). Thus, as a result of supplying the coolant from the cooling unit 60 to the main pipe 30 at the desired total flow rate for the electronic units 20a to 20d, the coolant is supplied the electronic units 20a to 20d located in the routes 1 to 4 at the desired flow rates.

The flow rate determination unit 73 compares a supply flow rate of the coolant, which is obtained by receiving the detection signal of the flowmeter 63 of the cooling unit 60, with the desired total flow rate of the coolant for the electronic units 20a to 20d, and determines whether a difference therebetween is within a certain range (step S22). The difference between the supply flow rate and the desired total flow rate being within the certain range may be, for example, the difference between the supply flow rate and the desired total flow rate being within ±5%, ±3%, or ±2% of the desired total flow rate. If the flow rate determination unit 73 determines that the difference between the flow rates is within the certain range (Yes), the flow rate determination unit 73 determines that the coolant is supplied to the electronic units 20a to 20d at desirable flow rates and powers on the electronic units 20a to 20d (causes the electronic units 20a to 20d to transition from a standby state to an operating state) (step S24). The process then ends. On the other hand, if the flow rate determination unit 73 determines that the difference between the flow rates is out of the certain range (No), the flow rate determination unit 73 determines that something is wrong with the input information and ends the process without powering on the electronic units 20a to 20d. When the process ends without power-on, for example, an alarm may be issued, or a message indicating that the information input to the storage unit 72 is wrong may be displayed on the PC 90.

According to the first embodiment, the plurality of valves 50a to 50d are controlled based on the desired flow rates of the coolant for the plurality of electronic units 20a to 20d and the information indicating the relationships between the pressure losses and the flow rates in the plurality of routes 1 to 4. Thus, the coolant may be distributed from the main pipe 30 to the plurality of routes 1 to 4 at the desired flow rates for the electronic units 20a to 20d, and the coolant may be caused to flow through the electronic units 20a to 20d at the desired flow rates. For example, even when the electronic units 20a to 20d of a plurality of kinds are housed in the single rack 10, a situation in which the coolant flows through a certain electronic unit in a concentrated manner is avoided and the occurrence of an electronic unit in which the flow rate of the coolant is insufficient is avoided. As a result of housing of the electronic units 20a to 20d of the plurality of kinds in the single rack 10 being enabled, increases in the number of racks 10 and in the number of cooling units 60 are avoided. The information on the desired flow rates of the coolant for the electronic units and the information indicating the relationships between the pressure losses and the flow rates are obtained in advance, and, by using these pieces of information, the coolant is caused to flow at the desired flow rates for the electronic units. Thus, the use of a temperature monitor and/or a flow rate monitor may be omitted. Consequently, a complicated mechanism for performing monitoring in real time by communication or the like may be avoided and high-density mounting of the electronic units may be enabled.

As in S16 to S20 in FIG. 6, the valves 50a to 50d are preferably controlled such that the pressure losses in the routes 1 to 4 in the case where the coolant flows through the routes 1 to 4 at the desired flow rates for the electronic units 20a to 20d are equal to each other. By making the pressure losses in the routes 1 to 4 when the coolant flows at the desired flow rates for the electronic units 20a to 20d be equal to each other, the coolant may be favorably distributed from the main pipe 30 to the routes 1 to 4 at favorable flow rates. The pressure losses being equal to each other is not limited to the case where the pressure losses are completely equal to each other, and the pressure losses may be substantially equal to each other to a degree with which the coolant may be distributed to the electronic units 20a to 20d at the desired flow rates for the electronic units 20a to 20d.

The pressure losses in the routes 1 to 4 are preferably the sums of the pressure losses in the internal flow passages 23 of the electronic units 20a to 20d, the pressure losses in the distribution pipes 40a to 40d, the pressure losses in the discharge pipes 41a to 41d, and the pressure losses in the valves 50a to 50d, respectively. This is because the pressure losses in the internal flow passages 23, the distribution pipes 40a to 40d, the discharge pipes 41a to 41d, and the valves 50a to 50d greatly affect the ease-of-flow of the coolant.

As in S12 to S20 in FIG. 6, from among the routes 1 to 4, the first route with the largest sum among the sums of the pressure losses in the internal flow passages 23 of the electronic units 20a to 20d, the pressure losses of the distribution pipes 40a to 40d, and the pressure losses of the discharge pipes 41a to 41d, respectively, is identified. The valve located in the first route among the valves 50a to 50d is controlled to have a certain opening degree. The opening degrees of the valves, among the valves 50a to 50d, located in the remaining routes among the routes 1 to 4 except for the first route are preferably controlled such that the pressure loss in each of the remaining routes is equal to the pressure loss in the first route. Consequently, the valves 50a to 50d may be easily controlled such that the pressure losses in the routes 1 to 4 are equal to each other.

As in S22 of FIG. 6, it is preferably determined, after the control of the valves 50a to 50d ends, whether the difference between the flow rate of the coolant supplied to the main pipe 30 and the desired total flow rate of the coolant for the electronic units 20a to 20d is within the certain range. Consequently, the occurrence of a failure, a decrease in lifetime, or the like in the electronic unit caused by the coolant not flowing at the desired flow rate for the electronic unit because of a reason such as the use of incorrect data information may be avoided and the electronic apparatus may be caused to stably operate.

In the first embodiment, the case where the information on the desired flow rates of the coolant for the electronic units, the information indicating the relationships between the pressure loss and the flow rate in the routes, and the information on the mounted positions of the electronic units in the rack are stored in the storage unit 72 has been described by way of example. However, the configuration is not limited to the case where these pieces of information are stored in the storage unit 72 included in the control unit 70, and the pieces of information may be stored in an external storage medium of the control unit 70 and may be read for use from this storage medium.

### Second Embodiment

In the case where coolant is supplied to the electronic units 20a to 20d, clogging may occur in a flow passage through which the coolant flows because of deposition of fine dust, precipitation of a foreign matter due to chemical reaction, propagation of bacteria, peeling of a component, and/or the like. For example, as illustrated in FIG. 2B, in the case where the coolant flows through between the heat dissipation fins 26, clogging is likely to occur since the interval X between the heat dissipation fins 26 is narrow. Accordingly, in a second embodiment, description will be given of a method for identifying an abnormal route after the coolant is supplied to the electronic units 20a to 20d at desired flow rates and the electronic units 20a to 20d are powered on in accordance with the flow rate adjusting method described in the first embodiment.

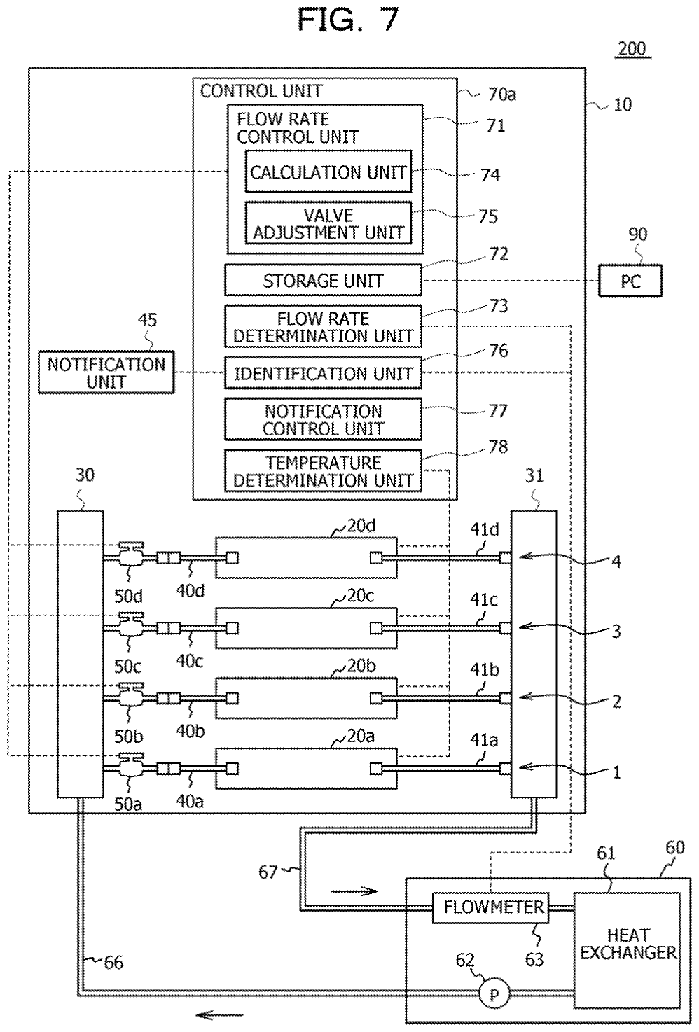

FIG. 7 is a schematic diagram of a control system of an electronic apparatus according to the second embodiment. In FIG. 7, control lines relating to a control unit 70a are indicated by dotted lines. FIG. 7 also illustrates a cooling system, which is the same as the cooling system illustrated in FIG. 1. As illustrated in FIG. 7, in an electronic apparatus 200 according to the second embodiment, the control unit 70a includes an identification unit 76, a notification control unit 77, and a temperature determination unit 78 in addition to the flow rate control unit 71, the storage unit 72, and the flow rate determination unit 73. The identification unit 76 receives a detection signal of the flowmeter 63 included in the cooling unit 60, and identifies an abnormal route based on the received result. The notification control unit 77 issues an alarm from a notification unit 45 in a case where the abnormal route occurs, a case where an abnormality occurs in the pump 62, or the like. The temperature determination unit 78 receives a detection signal of the thermometer 25 (see FIG. 2A) that measures a temperature of the heat generator 22 of the electronic unit 20 and determines, based on the received result, whether a temperature abnormality has occurred in the electronic unit 20. The identification unit 76, the notification control unit 77, and the temperature determination unit 78 are implemented by cooperation of hardware such as the CPU 80 and software stored in the nonvolatile memory 83 or the like.

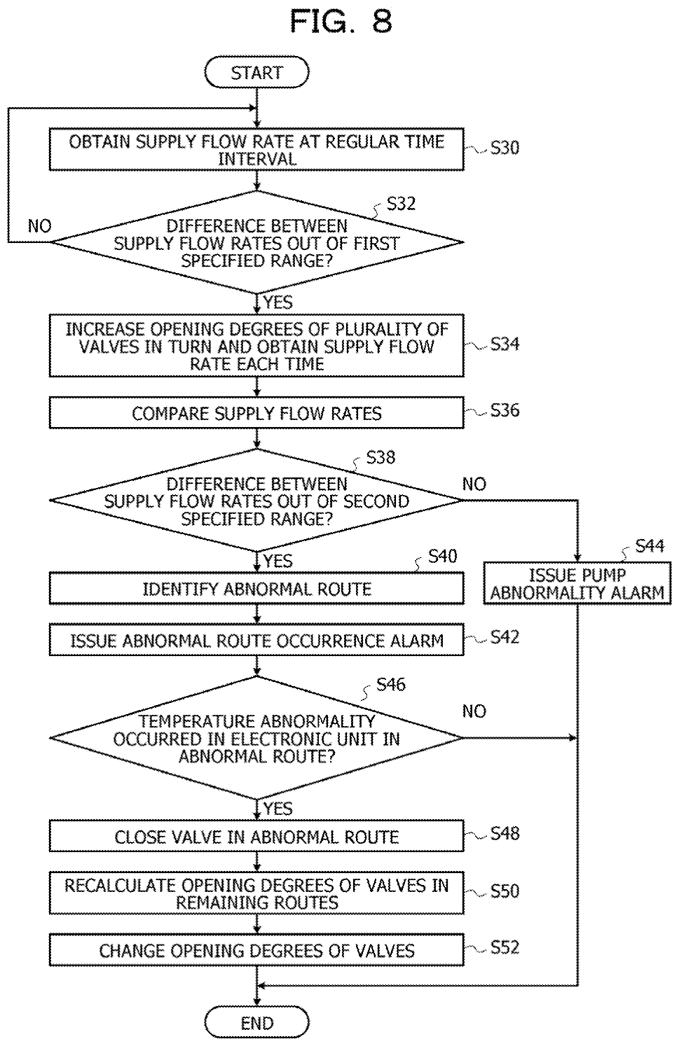

FIG. 8 is a flowchart illustrating an example of an abnormal route identifying method and an optimizing method performed after the occurrence of an abnormal route in the electronic apparatus according to the second embodiment. The flowchart of FIG. 8 is performed after the flowchart of FIG. 6 described in the first embodiment is performed and the electronic units 20a to 20d are powered on. As illustrated in FIG. 8, the flow rate determination unit 73 receives the detection signal of the flowmeter 63 of the cooling unit 60 at a regular time interval, and obtains, based on the received result, a supply flow rate of the coolant supplied from the cooling unit 60 to the main pipe 30 (step S30). The regular time interval is, for example, several minutes and, in one example, is five minutes.

The flow rate determination unit 73 determines whether a difference between the supply flow rate of the coolant to the main pipe 30 immediately after the flow rate of the coolant is adjusted (the supply flow rate of the coolant obtained in step S22 of FIG. 6) and the latest supply flow rate of the coolant to the main pipe 30 is out of a first specified range (step S32). The first specified range may be set such that, for example, the difference between the supply flow rate immediately after the flow rate adjustment and the latest supply flow rate is within 10%, 8%, or 5% of the supply flow rate immediately after the flow rate adjustment. In one example, in the case where the supply flow rate immediately after the flow rate adjustment is 100 [L/min], Yes is determined in step S32 if the latest supply flow rate is less than 90 [L/min].

If the difference between the supply flow rate immediately after the flow rate adjustment and the latest supply flow rate is within the first specified range (No), the process returns to step S30. On the other hand, if the difference between the supply flow rate immediately after the flow rate adjustment and the latest supply flow rate is out of the first specified range (Yes), the process proceeds to step S34. In step S34, the flow rate control unit 71 calculates the opening degrees of the valves 50a to 50d with which the flow rate of the coolant supplied to the main pipe 30 increases by a certain flow rate, and changes the opening degrees of the valves 50a to 50d to the calculated opening degrees in turn. Each time the opening degrees of the valves 50a to 50d are changed in turn, the identification unit 76 obtains, based on the detection signal of the flowmeter 63 of the cooling unit 60, the supply flow rate of the coolant supplied from the cooling unit 60 to the main pipe 30.

For example, the flow rate control unit 71 calculates the opening degree of the valve 50a with which the flow rate of the coolant supplied to the main pipe 30 (the total flow rate of the coolant that flows through the routes 1 to 4) increases by a certain flow rate (first flow rate). The flow rate control unit 71 increases the opening degree of the valve 50a located in the route 1 to the calculated opening degree. The opening degree of the valve 50a for causing the flow rate of the coolant supplied to the main pipe 30 to increase by the certain flow rate (first flow rate) is calculated by using the following method. In the following description, a case where the flow rate of the coolant supplied to the main pipe 30 increases by 3 [1/min] will be described by way of example. The opening degree of the valve 50a located in the route 1 is increased from k_{A} to k_{A}′. K_{A}′ may be appropriately set. Suppose that the flow rate of the coolant that flows through the route 1 at this time is denoted by Q_{A}′. In such a case, a pressure loss ΔP₁′ in the route 1 is calculated as ΔP₁′=α_{A}Q_{A}′\hat{ }β_{A}+2α_{A}Q_{A}′\hat{ }β_{I}+α(k_{A}′)Q_{A}′\hat{ }(k_{A}′).

As a result of the opening degree of the valve 50a in the route 1 being changed, the condition that all the pressure losses in the routes 1 to 4 are equal to each other collapses. Thus, the flow rates of the coolant that flows through the routes 2 to 4 also change. For example, as a result of an increase in the amount of the coolant that flows through the route 1 in response to an increase in the opening degree of the valve 50a, the flow rates of the coolant that flows through the routes 2 to 4 slightly decrease. Pressure losses ΔP₂′ to ΔP₄′ in the routes 2 to 4 at this time are calculated as follows: ΔP₂′=α_{B}Q_{B}′\hat{ }β_{B}+2α_{B}Q_{B}′\hat{ }β_{I}+α(k_{B})Q_{B}′\hat{ }β(k_{B}); ΔP₃′=α_{C}Q_{C}′ \hat{ }β_{C}+2α_{I}Q_{C}′\hat{ }β_{I}+α(k_{C})Q_{C}′\hat{ }β(k_{C}); and ΔP₄′=α_{D}Q_{D}′\hat{ }β_{D}+2α_{I}Q_{D}′\hat{ }β_{I}+α(k_{D})Q_{D}′\hat{ }β(k_{D}), where K_{B}, k_{C}, and k_{D} are values determined in the flowchart of FIG. 6.

In the aforementioned ΔP₁′ to ΔP₄′, Q_{A}′ to Q_{D}′ that satisfy ΔP₁′=ΔP₂′=ΔP₃′=ΔP₄′ are calculated, and a total flow rate value Q′ (Q′=Q_{A}′+Q_{B}′+Q_{C}′+Q_{D}′) of Q_{A}′ to Q_{D}′ is calculated. The total flow rate value Q′ is compared with a total flow rate value Q (Q=Q_{A}+Q_{B}+Q_{C}+Q_{D}) of the flow rates Q_{A} to Q_{D} of the coolant that flows through the routes 1 to 4 when the opening degrees of the valves 50a to 50d in the routes 1 to 4 are k_{A} to k_{D}, respectively, and the pressure losses in the routes 1 to 4 are equal to each other. If the total flow rate value Q′ increases from the total flow rate value Q by 3 [L/min], it is determined that the opening degree of the valve 50a located in the route 1 is to be k_{A}′. If the total flow rate value Q increases or decreases from the total flow rate value Q by an amount other than 3 [L/min], the opening degree of the valve 50a located in the route 1 is changed from k_{A}′ and recalculation is performed. The similar operation is performed for the valves 50b to 50d in the routes 2 to 4, and the opening degrees k_{B}′, k_{C}′, and k_{D}′ in the case where the total flow rate value when the opening degrees of the valves 50b to 50d are changed increases from the total flow rate value Q by 3 [L/min] are determined by calculation, respectively.

Thus, in step S34, the flow rate control unit 71 increases the opening degree of the valve 50a located in the route 1 to the opening degree calculated such that the coolant supplied to the main pipe 30 increases by the certain flow rate (first flow rate). The opening degrees of the valves 50b to 50d respectively located in the routes 2 to 4 are not changed. The identification unit 76 obtains, based on the detection signal of the flowmeter 63, the supply flow rate of the coolant supplied from the cooling unit 60 to the main pipe 30 when the opening degree of the valve 50a located in the route 1 is increased. The flow rate control unit 71 returns the opening degree of the valve 50a located in the route 1 to the original state.

The flow rate control unit 71 increases the opening degree of the valve 50b located in the route 2 to the opening degree calculated such that the flow rate of the coolant supplied to the main pipe 30 increases by the certain flow rate (first flow rate). The opening degrees of the valves 50a, 50c, and 50d respectively located in the routes 1, 3, and 4 are not changed. The opening degree of the valve 50b is calculated by using the same method as that for the opening degree of the valve 50a in the route 1 as described above. The identification unit 76 obtains, based on the detection signal of the flowmeter 63, the supply flow rate of the coolant supplied from the cooling unit 60 to the main pipe 30 when the opening degree of the valve 50b located in the route 2 is increased. The flow rate control unit 71 returns the opening degree of the valve 50b located in the route 2 to the original state.

The similar operation is performed for the routes 3 and 4. For example, the flow rate control unit 71 increases the opening degree of the valve 50c located in the route 3 to the opening degree calculated such that the flow rate of the coolant supplied to the main pipe 30 increases by the certain flow rate (first flow rate). The opening degrees of the valves 50a, 50b, and 50d respectively located in the routes 1, 2, and 4 are not changed. The opening degree of the valve 50c is calculated by using the same method as that for the opening degree of the valve 50a in the route 1 as described above. The identification unit 76 obtains, based on the detection signal of the flowmeter 63, the supply flow rate of the coolant supplied from the cooling unit 60 to the main pipe 30 when the opening degree of the valve 50c located in the route 3 is increased. The flow rate control unit 71 returns the opening degree of the valve 50c located in the route 3 to the original state. The flow rate control unit 71 increases the opening degree of the valve 50d located in the route 4 to the opening degree calculated such that the flow rate of the coolant supplied to the main pipe 30 increases by the certain flow rate (first flow rate). The opening degrees of the valves 50a to 50c respectively located in the routes 1 to 3 are not changed. The opening degree of the valve 50d is calculated by using the same method as that for the opening degree of the valve 50a in the route 1 as described above. The identification unit 76 obtains, based on the detection signal of the flowmeter 63, the supply flow rate of the coolant supplied from the cooling unit 60 to the main pipe 30 when the opening degree of the valve 50d located in the route 4 is increased. The flow rate control unit 71 returns the opening degree of the valve 50d located in the route 4 to the original state.

The identification unit 76 compares the supply flow rates, obtained in step S34, of the coolant supplied to the main pipe 30 with each other (step S36). For example, the identification unit 76 compares the supply flow rate obtained when the opening degree of the valve 50a located in the route 1 is increased with the supply flow rates obtained when the opening degrees of the valves 50b to 50d located in the routes 2 to 4 are increased, and obtains differences therebetween. The identification unit 76 compares the supply flow rate obtained when the opening degree of the valve 50b located in the route 2 is increased with the supply flow rates obtained when the opening degrees of the valves 50c and 50d located in the routes 3 and 4 are increased, and obtains differences therebetween. The identification unit 76 compares the supply flow rate obtained when the opening degree of the valve 50c located in the route 3 is increased with the supply flow rate obtained when the opening degree of the valve 50d located in the route 4 is increased, and obtains a difference therebetween.

For example, it is assumed that the supply flow rate of the coolant supplied to the main pipe 30, which is obtained based on the detection signal of the flowmeter 63 when Yes is determined in step S32, is 84 [L/min]. It is assumed that the opening degrees of the valves 50a to 50d are increased in turn so that the flow rate of the coolant supplied to the main pipe 30 increases each time by 3 [L/min] by calculation in step S34. In this case, it is assumed that the supply flow rate detected by the flowmeter 63 when the opening degree of the valve 50a in the route 1 is increased is 87 [L/min]. It is assumed that the supply flow rate detected by the flowmeter 63 when the opening degree of the valve 50b in the route 2 is increased is 86.9 [L/min]. It is assumed that the supply flow rate detected by the flowmeter 63 when the opening degree of the valve 50c in the route 3 is increased is 87.1 [L/min]. It is assumed that the supply flow rate detected by the flowmeter 63 when the opening degree of the valve 50d in the route 4 is increased is 86.1 [L/min].

In such a case, the difference in supply flow rate of the coolant supplied to the main pipe 30 between when the opening degree of the valve 50a located in the route 1 is increased and when the opening degree of the valve 50b located in the route 2 is increased is calculated to be 87-86.9=0.1 [L/min]. Likewise, the difference in supply flow rate between the route 1 and the route 3 is calculated to be −0.1 [L/min], and the difference in supply flow rate between the route 1 and the route 4 is calculated to be 0.9 [L/min]. The difference in supply flow rate between the route 2 and the route 3 is calculated to be −0.2 [L/min], the difference in supply flow rate between the route 2 and the route 4 is calculated to be 0.8 [1/min], and the difference in supply flow rate between the route 3 and the route 4 is calculated to be 1.0 [L/min].

The identification unit 76 determines whether there is a difference that is out of a second specified range among the differences in supply flow rates of the coolant supplied to the main pipe 30 that are compared in step S36 (step S38). The second specified range may be, for example, within 0.8 [L/min] but may be within 0.7 [L/min], 0.6 [L/min], or 0.5 [L/min]. The second specified range may be set such that the difference in supply flow rate of the coolant is within 0.8%, 0.6%, or 0.4% of the supply flow rate of the coolant before the opening degrees of the valves 50a to 50d are increased.

If there is a difference in supply flow rate of the coolant supplied to the main pipe 30 that is out of the second specified range in step S38 (Yes), the identification unit 76 identifies, based on the results of the differences in supply flow rate of the coolant, an abnormal route in which an abnormality such as flow passage clogging has occurred (step S40). The notification control unit 77 issues, from the notification unit 45, an alarm indicating the abnormal route in which the abnormality has occurred (step S42). For example, the case is assumed where the supply flow rates detected by the flowmeter 63 when the opening degrees of the valves 50a to 50d are increased in turn are as described above. In this case, the difference between the supply flow rate when the opening degree of the valve 50d located in the route 4 is increased and the supply flow rate when the opening degree of each of the valves 50a to 50c respectively located in the routes 1 to 3 is increased is out of the second specified range. Thus, the identification unit 76 identifies that an abnormality such as flow passage dogging has occurred in the route 4, and the notification control unit 77 issues an alarm.

On the other hand, if there is no difference in supply flow rate of the coolant supplied to the main pipe 30 that is out of the second specified range in step S38 (No), the notification control unit 77 issues, from the notification unit 45, an alarm indicating that an abnormality has occurred in the pump 62 (step S44). The process then ends. This is because it is considered that the reason why the difference in supply flow rate of the coolant supplied to the main pipe 30 is out of the first specified range in step S32 is not because of flow passage dogging or the like but because of an abnormality in the pump 62.

After step S42, the temperature determination unit 78 obtains the temperature of the heat generator 22 of the electronic unit located in the abnormal route, based on the detection signal of the thermometer 25 (see FIG. 2A) and determines whether a temperature abnormality has occurred in the electronic unit (step S46). For example, when the temperature obtained based on the detection signal of the thermometer 25 is higher than or equal to a certain temperature, the temperature determination unit 78 determines that a temperature abnormality has occurred in the electronic unit. The certain temperature is, for example, 80° C. If no temperature abnormality has occurred in the electronic unit (No in step S46), it may be determined that the coolant is flowing to an extent with which the temperature of the electronic unit is maintained low even if there is flow passage dogging. Thus, the process ends.

On the other hand, if a temperature abnormality has occurred in the electronic unit (Yes in step S46), the flow rate control unit 71 closes the valve located in the abnormal route (step S48). Consequently, the coolant is no longer supplied to the abnormal route, and the electronic unit in the abnormal route may be powered off and replaced or the like.

The flow rate control unit 71 recalculates the opening degrees of the valves located in the remaining routes other than the abnormal route (step S50). In the recalculation of the opening degrees of the valves, the opening degrees of the valves are calculated with which the pressure losses in the remaining routes are made equal to each other, as in the method described in the flowchart of FIG. 6. Since details are described in FIG. 6, description is omitted. After the recalculation of the opening degrees of the valves ends, the flow rate control unit 71 changes the opening degrees of the valves located in the remaining routes (step S52).

According to the second embodiment, as in S32 to S40 in FIG. 8, when the flow rate of the coolant supplied to the main pipe 30 is out of the first specified range, an abnormal route is identified based on the supply flow rate of the coolant supplied to the main pipe 30. By identifying the abnormal route based on the supply flow rate of the coolant in this manner, the abnormal mute may be identified more accurately than, for example, when the abnormal route is identified based on the detection result of the thermometer 25 that measures the temperature of the heat generator 22. This is because the temperature of the heat generator 22 may increase because of an abnormality in the thermometer 25, an abnormality in the heat generator 22, an abnormality in the wiring board 21 and/or the like as well as a decrease in the coolant due to flow passage clogging. By identifying the abnormal route based on the supply flow rate of the coolant, the abnormal route may be identified more quickly than when the abnormal route is identified based on the detection result of the thermometer 25.

As in steps S34 to S40 in FIG. 8, the opening degrees of the valves 50a to 50d with which the flow rate of the coolant supplied to the main pipe 30 increases by the certain flow rate are calculated, and the opening degrees of the valves 50a to 50d are changed to the calculated opening degrees in turn. The case is preferable where the flow rate of the coolant supplied to the main pipe 30 is obtained each time the opening degrees of the valves 50a to 50d are changed in turn, and the abnormal route is identified based on the obtained flow rates of the coolant. Thus, the abnormal route may be identified accurately. In this case, the flow rates of the coolant supplied to the main pipe 30 may be obtained and compared with each other, and the abnormal route may be identified from the routes included in the case where the difference between the flow rates of the coolant is out of the second specified range. The obtained flow rate of the coolant may be compared with a flow rate that is to be supplied to the main pipe 30 in response to changing the opening degree of the valve such that the flow rate of the coolant increases by the certain flow rate, and the route in the case where a difference therebetween is out of a third specified range may be specified as the abnormal route. In the second embodiment, the case where the opening degrees of the valves 50a to 50d in the respective routes 1 to 4 are increased in turn such that the flow rate of the coolant supplied to the main pipe 30 increases by the certain flow rate has been described by way of example. However, the flow rate may decrease by a certain flow rate. In this case, since the flow rates of the coolant supplied to the electronic units momentarily decrease, it is preferable to check in advance that there is no influence on the electronic units.

As in S48 to S52 in FIG. 8, the valve located in the abnormal route is controlled, so that the coolant does not flow through the abnormal route. The valves located in the remaining routes other than the abnormal route are preferably controlled such that the pressure losses in the remaining routes in the case where the coolant flows through the electronic units located in the remaining routes at the desired flow rates are equal to each other. Consequently, for example, even when the electronic unit located in the abnormal route is replaced or the like, the coolant may be supplied to the electronic units in the routes other than the abnormal route at the desired flow rates and the electronic apparatus may be continuously used. The control of the valves for making the pressure losses in the remaining routes be equal to each other may be performed when the electronic unit in the abnormal route has a temperature abnormality. Consequently, the electronic unit in the abnormal route is allowed to operate immediately before a failure or the like may occur.

In the case where the abnormal route is identified, an alarm indicating the identified abnormal route may be issued. Consequently, the route in which an abnormality has occurred may be easily recognized.

While the embodiments of the present disclosure have been described in detail above, the present disclosure is not limited to such specific embodiments, and various modifications and alterations may be made within the scope of the gist of the present disclosure described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic apparatus comprising:
a plurality of electronic circuits of two or more kinds, that are housed in a rack and that have respective internal flow passages through which coolant flows;
a first pipe that is supplied with the coolant to flow through the internal flow passages of the plurality of electronic circuits;
a second pipe in which the coolant discharged from the plurality of electronic circuits joins together;
a plurality of distribution pipes that distribute the coolant from the first pipe to the plurality of electronic circuits;
a plurality of discharge pipes that allow the coolant discharged from the plurality of electronic circuits to join together in the second pipe;
a plurality of flow rate adjusting mechanisms that adjust flow rates of the coolant that flows into the plurality of distribution pipes from the first pipe; and
a flow rate control circuit that controls the plurality of flow rate adjusting mechanisms,
wherein the flow rate control circuit controls the plurality of flow rate adjusting mechanisms, based on desired flow rates of the coolant for the plurality of electronic circuits and information that indicates relationships between pressure losses and flow rates in a plurality of routes that include the internal flow passages of the plurality of electronic circuits, the plurality of distribution pipes, the plurality of discharge pipes, and the plurality of flow rate adjusting mechanisms and in which the coolant flows between the first pipe and the second pipe.

2. The electronic apparatus according to claim 1, wherein the flow rate control circuit controls the plurality of flow rate adjusting mechanisms such that the pressure losses in the plurality of routes in a case where the coolant flows through the plurality of routes at the desired flow rates for the plurality of electronic circuits located in the plurality of routes are equal to each other.

3. The electronic apparatus according to claim 1, wherein the pressure losses in the plurality of routes are sums of pressure losses in the internal flow passages of the plurality of electronic circuits, pressure losses in the plurality of distribution pipes, pressure losses in the plurality of discharge pipes, and pressure losses in the plurality of flow rate adjusting mechanisms, respectively.

4. The electronic apparatus according to claim 1, wherein the flow rate control circuit
identifies, from among the plurality of routes, a first route with a largest sum among sums of pressure losses in the internal flow passages of the plurality of electronic circuits, pressure losses in the plurality of distribution pipes, and pressure losses in the plurality of discharge pipes, respectively,
controls, among the plurality of flow rate adjusting mechanisms, a flow rate adjusting mechanism located in the first route, and
then controls, among the plurality of flow rate adjusting mechanisms, a flow rate adjusting mechanism in a remaining route among the plurality of routes except for the first route such that a pressure loss in the remaining route is equal to a pressure loss in the first route.

5. The electronic apparatus according to claim 1, further comprising:
a flow rate determination circuit that determines, after the control of the plurality of flow rate adjusting mechanisms by the flow rate control circuit ends, whether a difference between a flow rate of the coolant supplied to the first pipe and a sum of the desired flow rates of the coolant for the plurality of electronic circuits is within a certain range.

6. The electronic apparatus according to claim 1, further comprising:
an identification circuit that identifies, based on the flow rate of the coolant supplied to the first pipe, an abnormal route in which an abnormality has occurred from among the plurality of routes in a case where the flow rate of the coolant supplied to the first pipe is out of a first specified range in a state where the control of the plurality of flow rate adjusting mechanisms by the flow rate control circuit ends and the plurality of electronic circuits are powered on.

7. The electronic apparatus according to claim 6, wherein the identification circuit
obtains the flow rate of the coolant supplied to the first pipe each time opening degrees of the plurality of flow rate adjusting mechanisms are changed in turn to opening degrees calculated such that the flow rate of the coolant supplied to the first pipe changes by a certain flow rate, and
identifies the abnormal route based on the obtained flow rates of the coolant.

8. The electronic apparatus according to claim 6, wherein the identification circuit
obtains the flow rate of the coolant supplied to the first pipe each time opening degrees of the plurality of flow rate adjusting mechanisms are changed in turn to opening degrees calculated such that the flow rate of the coolant supplied to the first pipe changes by a certain flow rate,
compares the obtained flow rates with each other, and
identifies the abnormal route from among routes involved in a case where a difference between the flow rates of the coolant is out of a second specified range.

9. The electronic apparatus according to claim 6, wherein the flow rate control circuit
controls, among the plurality of flow rate adjusting mechanisms, a flow rate adjusting mechanism in the abnormal route identified by the identification circuit such that the coolant does not to flow through the abnormal route, and
then controls, among the plurality of flow rate adjusting mechanisms, flow rate adjusting mechanisms in remaining routes other than the abnormal route among the plurality of routes such that pressure losses in the remaining routes in a case where the coolant flows through the remaining routes at desired flow rates for electronic circuits located in the remaining routes among the plurality of electronic circuits are equal to each other.

10. The electronic apparatus according to claim 9, wherein in a case where a temperature of an electronic circuit located in the abnormal route among the plurality of electronic circuits is higher than or equal to a certain temperature, the flow rate control circuit controls the flow rate adjusting mechanisms located in the remaining routes such that the pressure losses in the remaining routes are equal to each other.

11. The electronic apparatus according to claim 6, further comprising:
a notification circuit that issues, in a case where the abnormal route is identified by the identification circuit, an alarm that indicates the identified abnormal route.

12. The electronic apparatus according to claim 1, wherein the plurality of flow rate adjusting mechanisms are valves whose opening degrees are adjustable.

13. The electronic apparatus according to claim 1, further comprising:
a storage circuit that stores information on the desired flow rates of the coolant, the information that indicates the relationships between the pressure losses and the flow rates in the plurality of routes, and information on mounted positions of the plurality of electronic circuits in the rack.

14. A method for controlling an electronic apparatus comprising:
supply, to a first pipe, coolant which flows through internal flow passages of a plurality of electronic circuits of two or more kinds that are housed in a rack;
joining, at a second pipe, the coolant discharged from the plurality of electronic circuits together,
distributing, by a plurality of distribution pipes, the coolant from the first pipe to the plurality of electronic circuits;
allowing, by a plurality of discharge pipes, the coolant discharged from the plurality of electronic circuits to join together in the second pipe;
adjusting, by a plurality of flow rate adjusting mechanisms, flow rates of the coolant that flows into the plurality of distribution pipes from the first pipe;
controlling, by a flow rate control circuit, the plurality of flow rate adjusting mechanisms; and
controlling, the flow rate control circuit, the plurality of flow rate adjusting mechanisms, based on desired flow rates of the coolant for the plurality of electronic circuits and information that indicates relationships between pressure losses and flow rates in a plurality of routes that include the internal flow passages of the plurality of electronic circuits, the plurality of distribution pipes, the plurality of discharge pipes, and the plurality of flow rate adjusting mechanisms and in which the coolant flows between the first pipe and the second pipe.
